(19) United States
(12) Patent Application Publication
(10) Pub. No.: US 2025/0294944 A1
(43) Pub. Date: Sep. 18, 2025

(54) DISPLAY DEVICE AND ELECTRONIC DEVICE INCLUDING THE SAME

(71) Applicant: Samsung Display Co., LTD., Yongin-si (KR)

(72) Inventor: MISUN LEE, Yongin-si (KR)

(21) Appl. No.: 19/035,480

(22) Filed: Jan. 23, 2025

(30) Foreign Application Priority Data
Mar. 12, 2024 (KR) 10-2024-0034426

(51) Int. Cl. H10H 29/49; H05K 1/02; H05K 1/18

(52) U.S. Cl. CPC H10H 29/49; H05K 1/0266; H05K 1/189; H05K 2201/10128

(57) ABSTRACT

A display device includes a display panel, a flexible circuit film attached on the display panel, and a conductive adhesive between the display panel and the flexible circuit film. The display panel may include a base substrate including a display area and a peripheral area, pads in the peripheral area and spaced apart from each other in a first direction, and a panel vernier mark in the peripheral area and spaced apart from the pads in the first direction. The pads may include a first pad extending in a second direction perpendicular to the first direction and a second pad extending to be inclined at a first angle with respect to the second direction. The panel vernier mark may include a first extension pattern extending in parallel to the first pad and a second extension pattern extending in parallel to the second pad.

### CROSS-REFERENCE TO RELATED APPLICATION

The present application claims priority to and the benefit of Korean Patent Application No. 10-2024-0034426, filed on Mar. 12, 2024, in the Korean Intellectual Property Office, the entire disclosure of which is incorporated herein by reference.

### BACKGROUND

### 1. Field

Aspects of some embodiments relate to a display device and an electronic device including the display device.

### 2. Description of the Related Art

Flat panel display devices are replacing cathode ray tube display devices as display devices due to their relatively lightweight and thin characteristics. As representative examples of such flat panel display devices, there are liquid crystal display devices and organic light emitting diode display devices.

The display device may include a display panel including a plurality of pixels and a flexible circuit film that transmits electrical signals to the display panel. The display panel and the flexible circuit film may be physically and electrically coupled to each other through a conductive adhesive. When the display panel and the flexible circuit film are coupled in a misaligned state, a reliability of the display device may decrease.

The above information disclosed in this Background section is only for enhancement of understanding of the background and therefore the information discussed in this Background section does not necessarily constitute prior art.

### SUMMARY

Aspects of some embodiments include a display device with relatively improved reliability.

Aspects of some embodiments include an electronic device including the display.

Additional aspects of some embodiments of the present disclosure will be set forth in the description which follows, and in part will be more apparent from the description, or may be learned by practice of the disclosed embodiments.

A display device according to some embodiments may include a display panel, a flexible circuit film, and a conductive adhesive. According to some embodiments, the display panel may include a base substrate including a display area and a peripheral area outside the display area, pixels in the display area, pads in the peripheral area and spaced apart from each other in a first direction, and a panel vernier mark in the peripheral area and spaced apart from the pads in the first direction. According to some embodiments, the flexible circuit film may be attached on the display panel and may include a base film and leads on the base film. According to some embodiments, the leads may respectively overlap the pads in a plan view. According to some embodiments, the conductive adhesive may be between the display panel and the flexible circuit film and may respectively connect the pads and the leads. According to some embodiments, the pads may include a first pad extending in a second direction perpendicular to the first direction and a second pad extending to be inclined at a first angle with respect to the second direction. According to some embodiments, the panel vernier mark may include a first extension pattern extending in parallel to the first pad and a second extension pattern extending in parallel to the second pad.

According to some embodiments, the first extension pattern may extend in the second direction, and the second extension pattern may extend to be inclined at the first angle with respect to the second direction.

According to some embodiments, the second pad may be spaced apart from the first pad in the first direction. According to some embodiments, the first extension pattern may be spaced apart from the second pad in the first direction. According to some embodiments, the second extension pattern may be spaced apart from the first extension pattern in the first direction.

According to some embodiments, the first pad may be at a center among the pads, and the second pad may be at an outermost location among the pads.

According to some embodiments, the pads may further include a third pad between the first pad and the second pad and extending to be inclined at a second angle less than the first angle with respect to the second direction. According to some embodiments, the panel vernier mark may further include a third extension pattern extending in parallel to the third pad.

According to some embodiments, the third extension pattern may be between the first extension pattern and the second extension pattern and may extend to be inclined at the second angle with respect to the second direction.

According to some embodiments, the panel vernier mark may further include a first character pattern indicating an angle in which an extension direction of the second extension pattern is inclined with respect to the second direction.

According to some embodiments, the first character pattern may be adjacent to the second extension pattern.

According to some embodiments, the panel vernier mark may further include a fourth extension pattern extending in the first direction, and a fifth extension pattern extending in the first direction and spaced apart from the fourth extension pattern in the second direction.

According to some embodiments, the panel vernier mark may further include a second character pattern indicating a distance between the fourth extension pattern and the fifth extension pattern in the second direction.

According to some embodiments, the second character pattern may be adjacent to the fifth extension pattern.

According to some embodiments, the fourth extension pattern and the fifth extension pattern may be spaced apart from the first extension pattern and the second extension pattern in the first direction.

According to some embodiments, in a plan view, the conductive adhesive may overlap the first extension pattern and the second extension pattern and may not overlap the fourth extension pattern and the fifth extension pattern.

According to some embodiments, in a plan view, the flexible circuit film may overlap the first extension pattern and the second extension pattern and may not overlap the fourth extension pattern and the fifth extension pattern.

According to some embodiments, the leads may include a first lead extending in the second direction and overlapping the first pad in a plan view, and a second lead extending to be inclined at the first angle with respect to the second direction and overlapping the second pad in a plan view. According to some embodiments, the flexible circuit film may be spaced apart from the leads in the first direction and may further include a film vernier mark extending in parallel to the second lead.

According to some embodiments, the film vernier mark may overlap the second extension pattern in a plan view.

According to some embodiments, the first extension pattern, the second extension pattern, the fourth extension pattern, and the fifth extension pattern may be integrally formed.

According to some embodiments, the conductive adhesive may not overlap the first extension pattern, the second extension pattern, the fourth extension pattern, and the fifth extension pattern in a plan view.

According to some embodiments, the flexible circuit film may not overlap the first extension pattern, the second extension pattern, the fourth extension pattern, and the fifth extension pattern in a plan view.

A display device according to some embodiments may include a display panel, a flexible circuit film, and a conductive adhesive. According to some embodiments, the display panel may include a base substrate including a display area and a peripheral area outside the display area, pixels in the display area, pads in the peripheral area and spaced apart from each other in a first direction, and a panel vernier mark in the peripheral area and spaced apart from the pads in the first direction. According to some embodiments, the flexible circuit film may be attached on the display panel and may include a base film and leads on the base film. According to some embodiments, the leads may respectively overlap the pads in a plan view. According to some embodiments, the conductive adhesive may be between the display panel and the flexible circuit film and may respectively connect the pads and the leads. According to some embodiments, the pads may include a first pad extending in a second direction perpendicular to the first direction and a second pad extending to be inclined at a first angle with respect to the second direction. According to some embodiments, the panel vernier mark may include a first extension portion extending in parallel to the first pad, a second extension portion extending in parallel to the second pad and located in the first direction from the first extension portion, a third extension portion extending in the first direction and crossing the first extension portion and the second extension portion, and a fourth extension portion extending in the first direction, located in the second direction from the third extension portion, and crossing the first extension portion and the second extension portion.

An electronic device according to some embodiments may include a display device and a power supply configured to provide power to the display device. The display device may include a display panel, a flexible circuit film, and a conductive adhesive. According to some embodiments, the display panel may include a base substrate including a display area and a peripheral area outside the display area, pixels in the display area, pads in the peripheral area and spaced apart from each other in a first direction, and a panel vernier mark in the peripheral area and spaced apart from the pads in the first direction. According to some embodiments, the flexible circuit film may be attached on the display panel and may include a base film and leads on the base film. According to some embodiments, the leads may respectively overlap the pads in a plan view. According to some embodiments, the conductive adhesive may be between the display panel and the flexible circuit film and may respectively connect the pads and the leads. According to some embodiments, the pads may include a first pad extending in a second direction perpendicular to the first direction and a second pad extending to be inclined at a first angle with respect to the second direction. According to some embodiments, the panel vernier mark may include a first extension pattern extending in parallel to the first pad and a second extension pattern extending in parallel to the second pad.

According to some embodiments, the display panel and the flexible circuit film may be precisely aligned to each other, thus, a reliability of the display device may be relatively improved.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the invention.

FIG. 1 is a plan view illustrating a display device according to some embodiments.

FIG. 2 is a circuit diagram illustrating a pixel included in the display device of FIG. 1.

FIG. 3 is a cross-sectional view illustrating the pixel of FIG. 2.

FIG. 4 is an enlarged view illustrating an example of an area A of FIG. 1.

FIG. 5 is an exploded plan view of the display device of FIG. 4.

FIG. 6 is an enlarged view illustrating a panel vernier mark of FIG. 5.

FIG. 7 is an enlarged view illustrating another example of an area A of FIG. 1.

FIG. 8 is an exploded plan view of the display device of FIG. 7.

FIG. 9 is an enlarged view illustrating a panel vernier mark of FIG. 8.

FIG. 10 is a block diagram illustrating an electronic device according to some embodiments.

### DETAILED DESCRIPTION

Aspects of some embodiments of the present disclosure will now be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being related to another element such as being “on” another element, it can be directly on the other element or intervening elements may be present therebetween. In contrast, when an element is referred to as being related to another element such as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, a reference number may indicate a singular element or a plurality of the element. For example, a reference number labeling a singular form of an element within the drawing figures may be used to reference a plurality of the singular element within the text of specification.

As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Illustrative, non-limiting embodiments will be more clearly understood from the following detailed description in conjunction with the accompanying drawings.

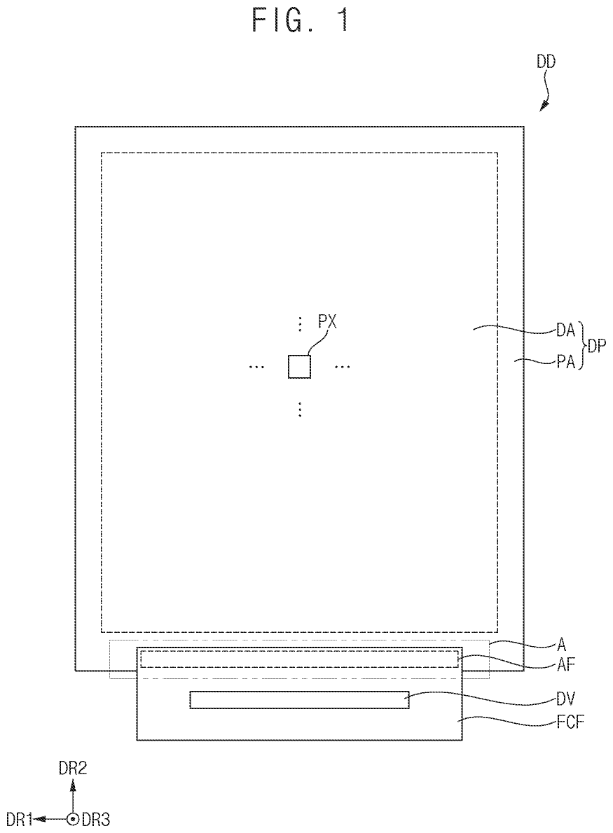

FIG. 1 is a plan view illustrating a display device according to some embodiments.

Referring to FIG. 1, a display device DD according to some embodiments may include a display panel DP, a flexible circuit film FCF, a conductive adhesive AF, and a driving circuit DV.

The display panel DP may have a display surface defined by a first direction DR1 and a second direction DR2 crossing the first direction DR1. The display panel DP may display images in a third direction DR3 through the display surface. For example, the second direction DR2 may be perpendicular to the first direction DR1. The third direction DR3 may be parallel (or substantially parallel) to a normal direction of the display surface. The display surface may correspond to an upper surface (or a front surface) of the display panel DP. Hereinafter, the third direction DR3 may be referred to as an upper direction, and a direction opposite to the third direction DR3 may be referred to as a lower direction.

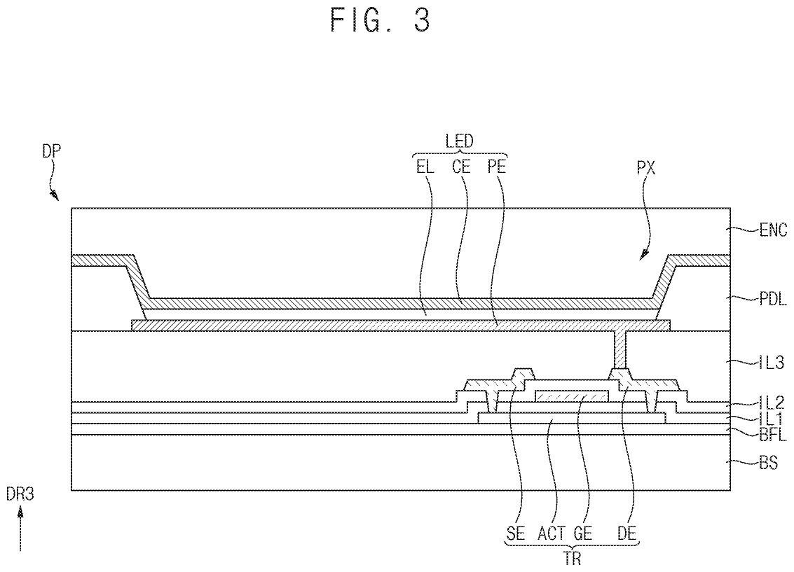

The display panel DP (or a base substrate BS of FIG. 3) may include a display area DA where images are displayed and a peripheral area PA located around (e.g., in a periphery or outside a footprint of) the display area DA. The peripheral area PA may be located outside the display area DA. For example, the peripheral area PA may surround the display area DA in a plan view (e.g., a view toward a display surface of the display area DA).

The display panel DP may include a plurality of pixels PX located in the display area DA. For example, the pixels PX may be arranged in a matrix form or arrangement in the first direction DR1 and the second direction DR2 in a plan view, but this is an example and embodiments are not limited thereto.

Each of the pixels PX may include a pixel circuit and a light emitting element. The pixel circuit may include at least one thin film transistor and at least one capacitor. The thin film transistor may generate a driving current and provide the generated driving current to the light emitting element. The light emitting element may emit light based on the driving current. For example, the light emitting element may include an organic light emitting diode, an inorganic light emitting diode, a quantum dot light emitting diode, or the like. The image may be generated by combining light emitted from each of the pixels PX.

The peripheral area PA may include a pad area located at one side of the display area DA. For example, the pad area may be located in a direction opposite to the second direction DR2 from the display area DA. The display panel DP may include a plurality of pads located in the pad area and electrically connected to the pixels PX.

The flexible circuit film FCF may be attached on the display panel DP. The flexible circuit film FCF may be attached on one side of the display panel DP. The flexible circuit film FCF may be attached on the display panel DP such that a first end portion of the flexible circuit film overlaps the pad area. The flexible circuit film FCF may include a plurality of leads located in the first end portion.

The conductive adhesive AF may be located between the display panel DP and the flexible circuit film FCF to couple the display panel DP and the flexible circuit film FCF to each other. The conductive adhesive AF may have both conductivity and adhesion. Thus, the conductive adhesive AF may physically and electrically couple the display panel DP and the flexible circuit film FCF to each other. The conductive adhesive AF may electrically connect the pads of the display panel DP and the leads of the flexible circuit film FCF, respectively. For example, the conductive adhesive AF may include an anisotropic conductive adhesive film (ACF).

The driving circuit DV may generate an electrical signal provided to the display panel DP and/or may process an electrical signal provided from the display panel DP. For example, the driving circuit DV may include a gate driving circuit for generating gate signals or a data driving circuit for generating data signals, but this is an example and embodiments are not limited thereto.

The driving circuit DV may be formed as an integrated circuit (IC). According to some embodiments, as illustrated in FIG. 1, the driving circuit DV may be directly mounted on one surface of the flexible circuit film FCF by a chip on film (COF) method. According to some embodiments, the driving circuit DV may be directly mounted on one surface of the display panel DP by a chip on glass (COG) method or a chip on plastic (COP) method.

According to some embodiments, a circuit board may be connected to a second end portion of the flexible circuit film FCF opposite to the first end portion. The flexible circuit film FCF may be flexible. For example, the flexible circuit film FCF may be bent so that the driving circuit DV and the circuit board are located below the display panel DP.

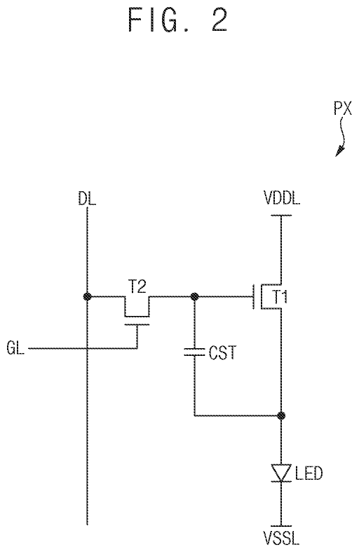

FIG. 2 is a circuit diagram illustrating a pixel included in the display device of FIG. 1. FIG. 3 is a cross-sectional view illustrating the pixel of FIG. 2.

Hereinafter, the pixels PX located in the display area DA of the display panel DP will be described in more detail with reference to FIGS. 2 and 3. Although FIGS. 2 and 3 illustrate various components in a pixel PX according to some embodiments, embodiments according to the present disclosure are not limited thereto, and according to some embodiments, the pixel PX may include additional components without departing from the spirit and scope of embodiments according to the present disclosure.

Referring to FIG. 2, each of the pixels PX may include the pixel circuit and the light emitting element LED. The pixel circuit may include a first transistor T1, a second transistor T2, and a storage capacitor CST.

The first transistor T1 may be configured to provide a driving current to the light emitting element LED. A first electrode of the first transistor T1 may be connected to a first power line VDDL that transmits a first power voltage, and a second electrode of the first transistor T1 may be connected to a first electrode of the light emitting element LED. A gate electrode of the first transistor T1 may be connected to a second electrode of the second transistor T2.

The second transistor T2 may be configured to provide a data signal to the gate electrode of the first transistor T1 in response to a gate signal. A first electrode of the second transistor T2 may be connected to a data line DL that transmits the data signal, and the second electrode of the second transistor T2 may be connected to the gate electrode of the first transistor T1. A gate electrode of the second transistor T2 may be connected to a gate line GL that transmits the gate signal.

FIG. 2 illustrates that each of the first transistor T1 and the second transistor T2 is an NMOS transistor, but this is an example and embodiments are not limited thereto. According to some embodiments, at least one of the first transistor T1 or the second transistor T2 may be a PMOS transistor.

The storage capacitor CST may maintain a voltage between the second electrode and the gate electrode of the first transistor T1. A first electrode of the storage capacitor CST may be connected to the gate electrode of the first transistor T1, and a second electrode of the storage capacitor CST may be connected to the second electrode of the first transistor T1.

FIG. 2 illustrates that the pixel circuit includes two transistors and one capacitor, but this is an example and embodiments are not limited thereto. According to some embodiments, the pixel circuit may include three or more transistors and/or two or more capacitors.

The light emitting element LED may emit light based on the driving current. The first electrode of the light emitting element LED may be connected to the second electrode of the first transistor T1, and a second electrode of the light emitting element LED may be connected to a second power line VSSL that transmits a second power voltage. For example, the first power voltage may be greater than the second power voltage.

Referring to FIG. 3, according to some embodiments, the display panel DP may include a base substrate BS, a buffer layer BFL, insulating layers IL1, IL2, and IL3, a transistor TR, a pixel defining layer PDL, the light emitting element LED, and an encapsulation layer ENC. For example, the transistor TR of FIG. 3 may be the first transistor T1 of FIG. 2.

According to some embodiments, the base substrate BS may be a transparent insulating substrate. For example, the base substrate BS may include a resin substrate or a glass substrate.

The buffer layer BFL may be located on the base substrate BS. The buffer layer BFL may prevent or reduce impurities or contaminants such as oxygen or moisture from penetrating into an upper portion of the base substrate BS through the base substrate BS. The buffer layer BFL may include an inorganic material. According to some embodiments, for example, the buffer layer BFL may include silicon oxide (SiO), silicon nitride (SIN), silicon oxynitride (SiON), silicon oxycarbide (SiOC), silicon carbonitride (SiCN), aluminum oxide (AlO), aluminum nitride (AlN), tantalum oxide (TaO), hafnium oxide (HfO), zirconium oxide (ZrO), titanium oxide (TiO), or the like. These can be used alone or in a combination thereof. The buffer layer BFL may have a single-layered structure or a multi-layered structure including a plurality of insulating layers.

The transistor TR may be located on the buffer layer BFL. The transistor TR may include an active layer ACT, a gate electrode GE, a first contact electrode SE, and a second contact electrode DE.

The active layer ACT may be located on the buffer layer BFL. The active layer ACT may include an oxide semiconductor, a silicon semiconductor, an organic semiconductor, or the like. According to some embodiments, for example, the oxide semiconductor may include at least one selected from oxides of indium (In), gallium (Ga), tin (Sn), zirconium (Zr), vanadium (V), hafnium (Hf), cadmium (Cd), germanium (Ge), chromium (Cr), titanium (Ti), and zinc (Zn). The silicon semiconductor may include an amorphous silicon, a polycrystalline silicon, or the like. The active layer ACT may include a source area, a drain area, and a channel area located between the source area and the drain area.

A first insulating layer IL1 may be located on the active layer ACT. The first insulating layer IL1 may cover the active layer ACT on the buffer layer BFL. The first insulating layer IL1 may include an inorganic insulating material.

The gate electrode GE may be located on the first insulating layer IL1. The gate electrode GE may overlap the channel area of the active layer ACT. The gate electrode GE may include a conductive material such as a metal, an alloy, a conductive metal nitride, a conductive metal oxide, a transparent conductive material, or the like. According to some embodiments, for example, the gate electrode GE may include gold (Au), silver (Ag), aluminum (Al), platinum (Pt), nickel (Ni), titanium (Ti), palladium (Pd), magnesium (Mg), calcium (Ca), lithium (Li), chromium (Cr), tantalum (Ta), tungsten (W), copper (Cu), molybdenum (Mo), scandium (Sc), neodymium (Nd), iridium (Ir), alloys containing aluminum, alloys containing silver, alloys containing copper, alloys containing molybdenum, aluminum nitride (AIN), tungsten nitride (WN), titanium nitride (TiN), chromium nitride (CrN), tantalum nitride (TaN), strontium ruthenium oxide (SrRuO), zinc oxide (ZnO), indium tin oxide (ITO), tin oxide (SnO), indium oxide (InO), gallium oxide (GaO), indium zinc oxide (IZO), or the like. These can be used alone or in a combination thereof. The gate electrode GE may have a single-layered structure or a multi-layered structure including a plurality of conductive layers.

A second insulating layer IL2 may be located on the gate electrode GE. The second insulating layer IL2 may cover the gate electrode GE on the first insulating layer IL1. The second insulating layer 140 may include an inorganic insulating material.

The first contact electrode SE and the second contact electrode DE may be located on the second insulating layer IL2. The first contact electrode SE and the second contact electrode DE may be connected to the source area and the drain area of the active layer ACT, respectively. Each of the first contact electrode SE and the second contact electrode DE may include a conductive material.

A third insulating layer IL3 may be located on the first contact electrode SE and the second contact electrode DE. The third insulating layer IL3 may include an organic insulating material. According to some embodiments, for example, the third insulating layer IL3 may include photoresist, polyacryl-based resin, polyimide-based resin, polyamide-based resin, siloxane-based resin, acryl-based resin, epoxy-based resin, or the like. These can be used alone or in a combination thereof.

FIG. 2 illustrates that three insulating layers and two conductive layers are located between the active layer ACT and the light emitting element LED, but this is an example and embodiments are not limited thereto. For example, four or more insulating layers and three or more conductive layers may be located between the active layer ACT and the light emitting element LED.

A first electrode PE of the light emitting element LED may be located on the third insulating layer IL3. The first electrode PE may be an anode. The first electrode PE may include a conductive material. The first electrode PE may have a single-layered structure or a multi-layered structure including a plurality of conductive layers. The first electrode PE may be connected to the second contact electrode DE of the transistor TR through a contact hole formed in the third insulating layer IL3.

The pixel defining layer PDL may be located on the first electrode PE. The pixel defining layer PDL may cover a peripheral portion of the first electrode PE and may define a pixel opening exposing a central portion of the first electrode PE. The pixel defining layer PDL may include an organic insulating material.

An emission layer EL may be located on the first electrode PE. The emission layer EL may be located at least in the pixel opening of the pixel defining layer PDL. In some embodiments, the emission layer EL may include at least one of an organic emission material or quantum dot.

According to some embodiments, the organic emission material may include a low molecular organic compound or a high molecular organic compound. Examples of the low molecular organic compound may include copper phthalocyanine, N,N′-diphenylbenzidine, tris-(8-hydroxyquinoline)aluminum, or the like. Examples of the high molecular organic compound may include poly(3,4-ethylenedioxythiophene), polyaniline, poly-phenylenevinylene, polyfluorene, or the like. These can be used alone or in a combination thereof.

According to some embodiments, the quantum dot may include a core including a Group II-VI compound, a Group III-V compound, a Group IV-VI compound, a Group IV element, and/or a Group IV compound. According to some embodiments, the quantum dot may have a core-shell structure including the core and a shell surrounding the core. The shell may serve as a protection layer for preventing or reducing instances of the core being chemically denatured to maintain semiconductor characteristics, and may serve as a charging layer for imparting electrophoretic characteristics to the quantum dot.

A second electrode CE of the light emitting element LED may be located on the emission layer EL. The second electrode CE may also be located on the pixel defining layer PDL. The second electrode CE may be a cathode. The second electrode CE may include a conductive material. The first electrode PE, the emission layer EL, and the second electrode CE may form the light emitting element LED. The light emitting element LED may include various functional layers (e.g., a hole injection layer, a hole transport layer, an electron transport layer, an electron injection layer, or the like) located between the first electrode PE and the emission layer EL and/or between the emission layer EL and the second electrode CE.

The encapsulation layer ENC may be located on the second electrode CE. The encapsulation layer ENC may include at least one inorganic encapsulation layer and at least one organic encapsulation layer. According to some embodiments, the encapsulation layer ENC may include a first inorganic encapsulation layer located on the second electrode CE, an organic encapsulation layer located on the first inorganic encapsulation layer, and a second inorganic encapsulation layer located on the organic encapsulation layer. The organic encapsulation layer may cover the entire display area DA. In addition, according to some embodiments, the display panel DP may further include various functional layers (e.g., a touch sensing layer, a color filter layer, a light collecting layer, or the like) located on the encapsulation layer ENC.

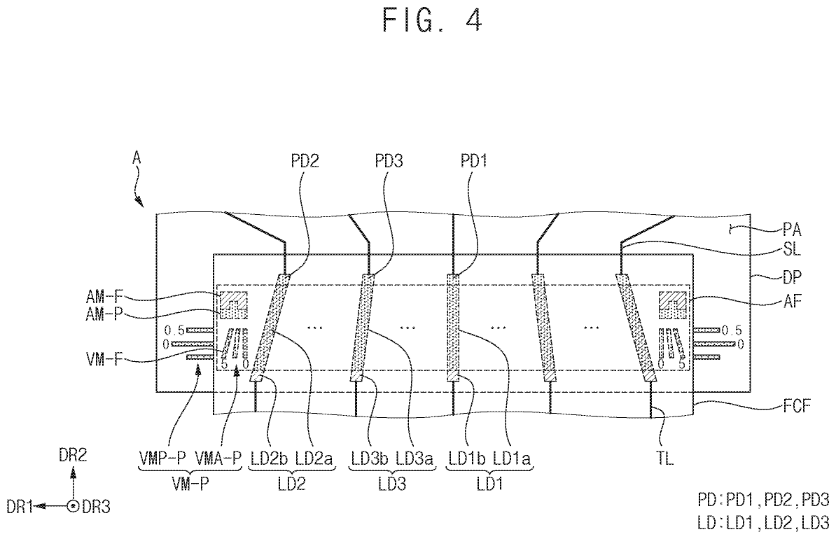

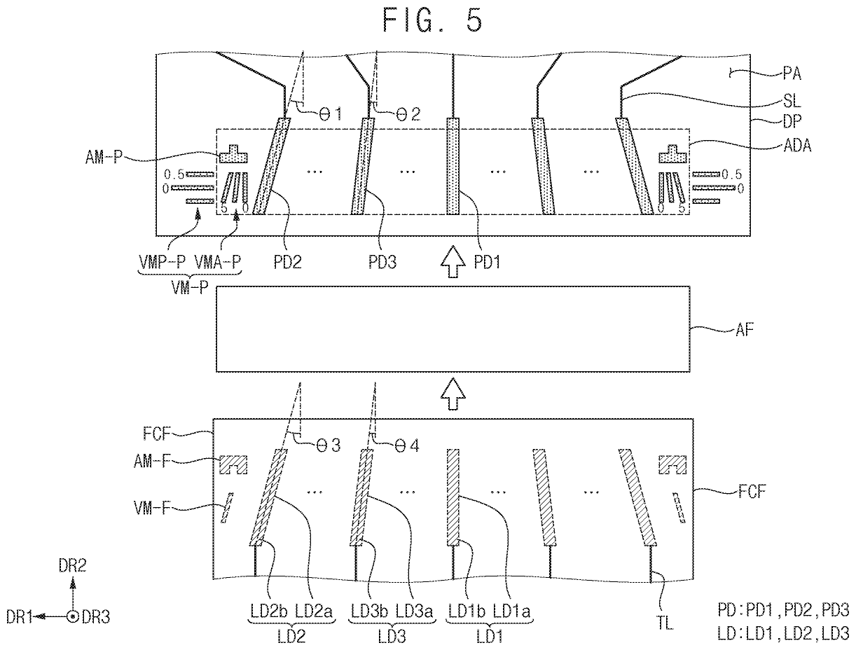

FIG. 4 is an enlarged view illustrating further details of the area A of FIG. 1. FIG. 5 is an exploded plan view of the display device of FIG. 4.

Hereinafter, the pad area of the display panel DP and the flexible circuit film FCF will be described in more detail with reference to FIGS. 4 and 5.

Referring to FIGS. 1, 4, and 5, the display panel DP may include the pixels PX located in the display area DA, and pads PD, a panel alignment mark AM-P, and a panel vernier mark VM-P located in the peripheral area PA. The pads PD, the panel alignment mark AM-P, and the panel vernier mark VM-P may be located on an upper surface of the base substrate BS of FIG. 3.

The flexible circuit film FCF may include a base film, and leads LD, a film alignment mark AM-F, and a film vernier mark VM-F located on one surface of the base film. The leads LD, the film alignment mark AM-F, and the film vernier mark VM-F may be located on a lower surface of the base film to respectively face the pads PD, the panel alignment mark AM-P, and the panel vernier mark VM-P.

The conductive adhesive AF may be located between the display panel DP and the flexible circuit film FCF. The conductive adhesive AF may be located on an adhesion area ADA of the display panel DP. The adhesion area ADA may be defined as an area where the conductive adhesive AF is located.

The pads PD may be located in the pad area of the peripheral area PA and may be spaced apart from each other in the first direction DR1. The pads PD may be electrically connected to the pixels PX in the display area DA through signal lines SL. The signal lines SL may include at least one of the data line DL, the gate line GL, or the first power line VDDL of FIG. 2. Electrical signals (e.g., the data signal, the gate signal, the first power voltage, or the like) transmitted from the flexible circuit film FCF may be provided to the pixels PX in the display area DA through the signal lines SL.

According to some embodiments, as illustrated in FIGS. 4 and 5, at least some of the pads PD spaced apart from each other in the first direction DR1 may extend to be inclined at different angles with respect to the second direction DR2. Hereinafter, an acute angle between an extension direction of each of the pads PD and the second direction DR2 may be referred to as an inclination angle.

According to some embodiments, a first pad PD1 may be located at a center in the first direction DR1 among the pads PD connected to the signal lines SL. As illustrated in FIG. 5, the pads PD may be arranged to be bilaterally symmetrical with respect to the first pad PD1. Hereinafter, for convenience of description, the pads PD will be described focusing on some pads located at the left (e.g., in the first direction DR1) of the first pad PD1.

The first pad PD1 may extend in the second direction DR2. An extension direction of the first pad PD1 may be parallel (or substantially parallel) to the second direction DR2. An inclination angle of the first pad PD1, which is an acute angle between the extension direction of the first pad PD1 and the second direction DR2, may be 0 degrees.

A second pad PD2 may be spaced apart from the first pad PD1 in the first direction DR1. For example, the second pad PD2 may be located at an outermost region (e.g., as the outermost pad) in the first direction DR1 among the pads PD connected to the signal lines SL. The second pad PD2 may extend to be inclined at a first angle θ1, which is greater than 0 degrees, with respect to the second direction DR2. An inclination angle of the second pad PD2, which is an acute angle between an extension direction of the second pad PD2 and the second direction DR2, may be the first angle θ1. The inclination angle of the second pad PD2 may be greater than the inclination angle of the first pad PD1.

A third pad PD3 may be located between the first pad PD1 and the second pad PD2. That is, the third pad PD3 may be spaced apart from the first pad PD1 in the first direction DR1 and may be spaced apart from the second pad PD2 in a direction opposite to the first direction DR1. The third pad PD3 may extend to be inclined at a second angle θ2, which is greater than 0 degrees and less than the first angle θ1, with respect to the second direction DR2. An inclination angle of the third pad PD3, which is an acute angle between an extension direction of the third pad PD3 and the second direction DR2, may be the second angle θ2. The inclination angle of the third pad PD3 may be greater than the inclination angle of the first pad PD1 and may be less than the inclination angle of the second pad PD2.

According to some embodiments, the pads PD between the first pad PD1 and the second pad PD2 may have different inclination angles. For example, the inclination angle may gradually increase from the first pad PD1 to the second pad PD2. According to some embodiments, at least some of the pads PD between the first pad PD1 and the second pad PD2 may have same inclination angles.

The leads LD may be spaced apart from each other in the first direction DR1. In a plan view, the leads LD may be arranged to overlap the pads PD, respectively. The leads LD may be electrically connected to the corresponding ones among the pads PD through the conductive adhesive AF, respectively.

Each of the leads LD may have a shape corresponding to a shape of corresponding one among the pads PD. According to some embodiments, as illustrated in FIG. 5, at least some of the leads LD spaced apart from each other in the first direction DR1 may extend to be inclined at different angles with respect to the second direction DR2. Hereinafter, an acute angle between an extension direction of each of the leads LD and the second direction DR2 may be referred to as an inclination angle.

According to some embodiments, a first lead LD1 corresponding to the first pad PD1 may be located at a center in the first direction DR1 among the leads LD connected to the pads PD. As illustrated in FIG. 5, the leads LD may be arranged to be bilaterally symmetrical with respect to the first lead LD1. Hereinafter, for convenience of description, the leads LD will be described focusing on some leads located to the left of the first lead LD1.

The first lead LD1 may extend in the second direction DR2. An extension direction of the first lead LD1 may be parallel (or substantially parallel) to the second direction DR2. An inclination angle of the first lead LD1, which is an acute angle between the extension direction of the first lead LD1 and the second direction DR2, may be 0 degrees.

A second lead LD2 corresponding to the second pad PD2 may be spaced apart from the first lead LD1 in the first direction DR1. For example, the second lead LD2 may be arranged to be at an outermost region (e.g., as the outermost lead among the leads LD) in the first direction DR1 among the leads LD connected to the pads PD. The second lead LD2 may extend to be inclined at a third angle θ3, which is greater than 0 degrees, with respect to the second direction DR2. An inclination angle of the second lead LD2, which is an acute angle between an extension direction of the second lead LD2 and the second direction DR2, may be the third angle θ3. The inclination angle of the second lead LD2 may be greater than the inclination angle of the first lead LD1. The third angle θ3 may be the same (or substantially the same) as the first angle θ1.

A third lead LD3 corresponding to the third pad PD3 may be located between the first lead LD1 and the second lead LD2. That is, the third lead LD3 may be spaced apart from the first lead LD1 in the first direction DR1 and may be spaced apart from the second lead LD2 in the direction opposite to the first direction DR1. The third lead LD3 may extend to be inclined at a fourth angle θ4, which is greater than 0 degrees and less than the third angle θ3, with respect to the second direction DR2. An inclination angle of the third lead LD3, which is an acute angle between an extension direction of the third lead LD3 and the second direction DR2, may be the fourth angle θ4. The inclination angle of the third lead LD3 may be greater than the inclination angle of the first lead LD1 and may be less than the inclination angle of the second lead LD2. The fourth angle θ4 may be the same (or substantially the same) as the second angle θ2.

According to some embodiments, in a plan view, one of the pads PD and one of the leads LD, which are corresponding to each other, may partially overlap each other. According to some embodiments, in a plan view, each of the pads PD may partially overlap the conductive adhesive AF. For example, as illustrated in FIG. 4, in a plan view, a portion of each of the pads PD may overlap the conductive adhesive AF, and a remaining portion (e.g., a portion in the second direction DR2) of each of the pads PD may not overlap the conductive adhesive AF.

According to some embodiments, in a plan view, each of the leads LD may partially overlap the conductive adhesive AF. For example, as illustrated in FIG. 4, each of the leads LD may include a first portion that overlaps the conductive adhesive AF and a second portion that does not overlaps the conductive adhesive AF.

The first lead LD1 may include a first portion LD1a that overlaps the conductive adhesive AF and a second portion LD1b that does not overlap the conductive adhesive AF. The first portion LD1a of the first lead LD1 may overlap the first pad PD1. The second lead LD2 may include a first portion LD2a that overlaps the conductive adhesive AF and a second portion LD2b that does not overlap the conductive adhesive AF. The first portion LD2a of the second lead LD2 may overlap the second pad PD2. The third lead LD3 may include a first portion LD3a that overlaps the conductive adhesive AF and a second portion LD3b that does not overlap the conductive adhesive AF. The first portion LD3a of the third lead LD3 may overlap the third pad PD3. The second portions LD1b, LD2b, and LD3b of the leads LD1, LD2, and LD3 may be located outside the conductive adhesive AF. That is, in a plan view, the second portions LD1b, LD2b, and LD3b of the leads LD1, LD2, and LD3 may extend from the conductive adhesive AF. Transmission lines TL may be connected to the second portions LD1b, LD2b, and LD3b of the leads LD1, LD2, and LD3, respectively.

The panel alignment mark AM-P may be located outside the pads PD. The film alignment mark AM-F may be located outside the leads LD. According to some embodiments, as illustrated in FIGS. 4 and 5, the panel alignment mark AM-P may be located on each of both sides of the pads PD, and the film alignment mark AM-F may be located on each of both sides of the leads LD. Hereinafter, the panel alignment mark AM-P and the film alignment mark AM-F located at the left (e.g., in the first direction DR1) of the pads PD and the leads LD will be described.

The panel alignment mark AM-P may be electrically insulated from the pixels PX and the pads PD. The panel alignment mark AM-P may be spaced apart from the pads PD in the first direction DR1. The film alignment mark AM-F may be electrically insulated from the leads LD. The film alignment mark AM-F may be spaced apart from the leads LD in the first direction DR1. According to some embodiments, each of the panel alignment mark AM-P and the film alignment mark AM-F may overlap the conductive adhesive AF. That is, the panel alignment mark AM-P may be located in the adhesion area ADA.

The panel alignment mark AM-P and the film alignment mark AM-F corresponding to each other may be used as a reference for an alignment between the display panel and the flexible circuit film FCF. According to some embodiments, after the conductive adhesive AF and the flexible circuit film FCF are provided on the display panel DP, the display panel DP and the flexible circuit film FCF may be aligned with each other using the panel alignment mark AM-P and the film alignment mark AM-F. For example, as illustrated in FIG. 4, the display panel DP and the flexible circuit film FCF may be aligned with each other such that the panel alignment mark AM-P and the film alignment mark AM-F form one alignment pattern, and may be coupled to each other. Afterwards, the display panel DP and the flexible circuit film FCF may be more precisely aligned with each other using the panel vernier mark VM-P and the film vernier mark VM-F, which will be described later.

The panel vernier mark VM-P may be located outside the pads PD. The film vernier mark VM-F may be located outside the leads LD. According to some embodiments, as illustrated in FIGS. 4 and 5, the panel vernier mark VM-P may be located on each of both sides of the pads PD, and the film vernier mark VM-F may be located on each of both sides of the leads LD. For example, the panel vernier marks VM-P located on each of both sides of the pads PD may be bilaterally symmetrical with respect to the first pad PD1. Hereinafter, the panel vernier mark VM-P and the film vernier mark VM-F located at the left (e.g., in the first direction DR1) of the pads PD and the leads LD will be described.

According to some embodiments, the panel vernier mark VM-P may include a first panel vernier mark VMA-P and a second panel vernier mark VMP-P. The first panel vernier mark VMA-P may be used as a reference for a twisting alignment of the display panel DP and the flexible circuit film FCF. The second panel vernier mark VMP-P may be used as a reference for a position alignment of the display panel DP and the flexible circuit film FCF.

According to some embodiments, as illustrated in FIGS. 4 and 5, each of the first panel vernier mark VMA-P and the film vernier mark VM-F may overlap the conductive adhesive AF in a plan view. That is, the first panel vernier mark VMA-P may be located in the adhesion area ADA in a plan view.

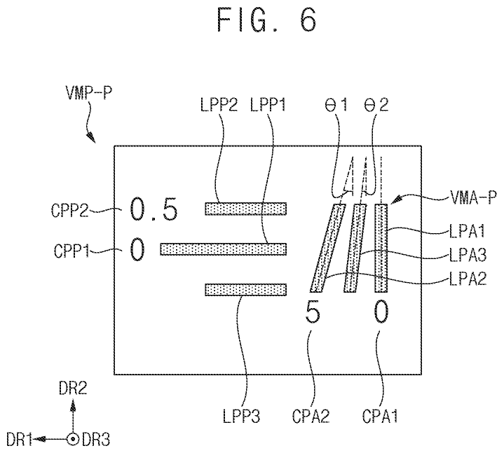

FIG. 6 is an enlarged view illustrating a panel vernier mark of FIG. 5.

Referring to FIGS. 4 to 6, according to some embodiments, the first panel vernier mark VMA-P may include first to third extension patterns LPA1, LPA2, and LPA3 spaced apart from each other in the first direction DR1. The first to third extension patterns LPA1, LPA2, and LPA3 may be electrically insulated from the pixels PX and the pads PD. The first to third extension patterns LPA1, LPA2, and LPA3 may extend to be inclined at different angles with respect to the second direction DR2. Hereinafter, an acute angle between an extension direction of each of the first to third extension patterns LPA1, LPA2, and LPA3 and the second direction DR2 may be referred to as an inclination angle.

The first extension pattern LPA1 may be spaced apart from the second pad PD2 in the first direction DR1. The first extension pattern LPA1 may be adjacent to the second pad PD2. The first extension pattern LPA1 may extend in parallel (or substantially in parallel) to the first pad PD1. That is, the first extension pattern LPA1 may extend in the second direction DR2. An extension direction of the first extension pattern LPA1 may be parallel (or substantially parallel) to the second direction DR2. An inclination angle of the first extension pattern LPA1, which is an acute angle between the extension direction of the first extension pattern LPA1 and the second direction DR2, may be 0 degrees.

The second extension pattern LPA2 may be spaced apart from the first extension pattern LPA1 in the first direction DR1. The second extension pattern LPA2 may extend in parallel (or substantially in parallel) to the second pad PD2. That is, the second extension pattern LPA2 may extend to be inclined at the first angle θ1 with respect to the second direction DR2. An inclination angle of the second extension pattern LPA2, which is an acute angle between an extension direction of the second extension pattern LPA2 and the second direction DR2, may be the first angle θ1. The inclination angle of the second extension pattern LPA2 may be greater than the inclination angle of the first extension pattern LPA1.

The third extension pattern LPA3 may be located between the first extension pattern LPA1 and the second extension pattern LPA2. That is, the third extension pattern LPA3 may be spaced apart from the first extension pattern LPA1 in the first direction DR1 and may be spaced apart from the second extension pattern LPA2 in the direction opposite to the first direction DR1. The third extension pattern LPA3 may extend in parallel (or substantially in parallel) to the third pad PD3. The third extension pattern LPA3 may extend to be inclined at the second angle θ2 with respect to the second direction DR2. An inclination angle of the third extension pattern LPA3, which is an acute angle between an extension direction of the third extension pattern LPA3 and the second direction DR2, may be the second angle θ2. The inclination angle of the third extension pattern LPA3 may be greater than the inclination angle of the first extension pattern LPA1 and may be less than the inclination angle of the second extension pattern LPA2.

The film vernier mark VM-F may be spaced apart from the second lead LD2 in the first direction DR1. The film vernier mark VM-F may be electrically insulated from the leads LD. The film vernier mark VM-F may extend in parallel (or substantially in parallel) to the second lead LD2. That is, the film vernier mark VM-F may extend to be inclined at the third angle θ3 with respect to the second direction DR2. An inclination angle of the film vernier mark VM-F, which is an acute angle between an extension direction of the film vernier mark VM-F and the second direction DR2, may be the third angle θ3. The third angle θ3 may be the same (or substantially the same) as the first angle θ1.

According to some embodiments, the film vernier mark VM-F may have a size and a shape corresponding to a size and a shape of the second extension pattern LPA2 of the first panel vernier mark VMA-P, and may be located (or formed) at a position corresponding to a position of the second extension pattern LPA2. For example, a distance between the second pad PD2 and the second extension pattern LPA2 in the first direction DR1 may be the same (or substantially the same) as a distance between the second lead LD2 and the film vernier mark VM-F in the first direction DR1. For example, as illustrated in FIG. 4, when the display panel DP and the flexible circuit film FCF are coupled to each other without error, the film vernier mark VM-F and the second extension pattern LPA2 may completely overlap each other.

The first panel vernier mark VMA-P and the film vernier mark VM-F may be used as a reference for the twisting alignment of the display panel DP and the flexible circuit film FCF. According to some embodiments, by measuring an angle between the second extension pattern LPA2 of the first panel vernier mark VMA-P and the film vernier mark VM-F using a magnifier or the like, a degree of twisting between the display panel DP and the flexible circuit film FCF may be accurately measured. Based on this, the flexible circuit film FCF may be rotated (or tilted) such that the second extension pattern LPA2 and the film vernier mark VM-F completely overlap each other, thus, the display panel DP and the flexible circuit Film FCF may be precisely aligned. Accordingly, a reliability of the display device DD may be relatively improved.

According to some embodiments, the first panel vernier mark VMA-P may further include a first-first character pattern CPA1 and a first-second character pattern CPA2.

The first-first character pattern CPA1 may be adjacent to the first extension pattern LPA1. The first-first character pattern CPA1 may indicate (or represent) an angle in which the extension direction of the first extension pattern LPA1 is inclined with respect to the second direction DR2. That is, the first-first character pattern CPA1 may indicate the inclination angle of the first extension pattern LPA1. For example, the first-first character pattern CPA1 may indicate 0 degrees.

The first-second character pattern CPA2 may be adjacent to the second extension pattern LPA2. The first-second character pattern CPA2 may indicate the first angle θ1 in which the extension direction of the second extension pattern LPA2 is inclined with respect to the second direction DR2. That is, the first-second character pattern CPA2 may indicate the inclination angle of the second extension pattern LPA2. FIG. 6 illustrates a shape of the first-second character pattern CPA2 in an example where the first angle θ1 is 5 degrees, but this is an example and the first angle θ1 may be variously modified between 0 degrees and 90 degrees, and the shape of the first-second character pattern CPA2 may also be variously modified.

According to some embodiments, as illustrated in FIGS. 4 and 5, the second panel vernier mark VMP-P may not overlap the conductive adhesive AF in a plan view. That is, the second panel vernier mark VMP-P may be located outside the conductive adhesive AF in a plan view. According to some embodiments, the second panel vernier mark VMP-P may not overlap the flexible circuit film FCF in a plan view.

According to some embodiments, as illustrated in FIG. 6, the second panel vernier mark VMP-P may include fourth to sixth extension patterns LPP1, LPP2, and LPP3 spaced apart from each other in the second direction DR2. The fourth to sixth extension patterns LPP1, LPP2, and LPP3 may be electrically insulated from the pixels PX and the pads PD.

The fourth extension pattern LPP1 may extend in the first direction DR1. The fourth extension pattern LPP1 may be spaced apart from the second extension pattern LPA2 in the first direction DR1. The fourth extension pattern LPP1 may be adjacent to the second extension pattern LPA2. For example, the fourth extension pattern LPP1 may be used as a guide to where a reference point marked on the flexible circuit film FCF should be located.

The fifth extension pattern LPP2 may extend in the first direction DR1. The fifth extension pattern LPP2 may be spaced apart from the fourth extension pattern LPP1 in the second direction DR2. According to some embodiments, a length of the fifth extension pattern LPP2 in the first direction DR1 may be less than a length of the fourth extension pattern LPP1 in the first direction DR1.

The sixth extension pattern LPP3 may extend in the first direction DR1. The sixth extension pattern LPP3 may be spaced apart from the fourth extension pattern LPP1 in the direction opposite to the second direction DR2. According to some embodiments, a length of the sixth extension pattern LPP3 in the first direction DR1 may be less than the length of the fourth extension pattern LPP1 in the first direction DR1. According to some embodiments, the length of the sixth extension pattern LPP3 in the first direction DR1 may be the same (or substantially the same) as the length of the fifth extension pattern LPP2 in the first direction DR1.

According to some embodiments, a distance between the fourth extension pattern LPP1 and the fifth extension pattern LPP2 in the second direction DR2 may be the same (or substantially the same) as a distance between the fourth extension pattern LPP1 and the sixth extension pattern LPP3 in the second direction DR2.

The second panel vernier mark VMP-P may be used as a reference for the position alignment of the display panel DP and the flexible circuit film FCF in the second direction DR2. According to some embodiments, by measuring a distance between the fourth extension pattern LPP1 and the reference point of the flexible circuit film FCF in the second direction DR2 using a magnifier or the like, a degree of position error in the second direction DR2 between the display panel DP and the flexible circuit film FCF may be accurately measured. In addition, by further measuring a distance between each of the fifth and sixth extension patterns LPP1 and LPP3 spaced apart from the fourth extension pattern LPP1 with an interval (e.g., a set or predetermined interval) and the reference point of the flexible circuit film FCF in the second direction DR2, the degree of position error in the second direction DR2 between the display panel DP and the flexible circuit film FCF may be more accurately measured. Based on this, the flexible circuit film FCF may be moved such that the reference point of the flexible circuit film FCF is located on the same line as the fourth extension pattern LPP1 (e.g., such that a distance between the reference point and the fourth extension pattern LPP1 in the second direction DR2 is zero), thus, the display panel DP and the flexible circuit Film FCF may be precisely aligned. Accordingly, the reliability of the display device DD may be relatively improved.

According to some embodiments, the second panel vernier mark VMP-P may further include a second-first character pattern CPP1 and a second-second character pattern CPP2.

The second-first character pattern CPP1 may be adjacent to the fourth extension pattern LPP1, and the second-second character pattern CPP2 may be adjacent to the fifth extension pattern LPP2. The second-second character pattern CPP2 may indicate (or represent) the distance between the fourth extension pattern LPP1 and the fifth extension pattern LPP2 in the second direction DR2. FIG. 6 illustrates a shape of the second-second character pattern CPP2 in an example where the distance between the fourth extension pattern LPP1 and the fifth extension pattern LPP2 in the second direction DR2 is 0.5 millimeters, but this is an example and the distance between the fourth extension pattern LPP1 and the fifth extension pattern LPP2 in the second direction DR2 may be variously modified, and the shape of the fi second-second character pattern CPP2 may also be variously modified.

According to some embodiments, the pads PD, the extension patterns LPA1, LPA2, LPA3, LPP1, LPP2, and LPP3, and the character patterns CPA1, CPA2, CPP1, and CPP2 may be located (or formed) on the same layer (or substantially the same layer). For example, the pads PD, the extension patterns LPA1, LPA2, LPA3, LPP1, LPP2, and LPP3, and the character patterns CPA1, CPA2, CPP1, and CPP2 may be located on the same layer (or substantially the same layer) as the gate electrode GE of FIG. 3, or may be located on the same layer (or substantially the same layer) as the first and second contact electrodes SE and DE of FIG. 3. But, this is an example and embodiments are not limited thereto. According to some embodiments, at least some of the pads PD, the extension patterns LPA1, LPA2, LPA3, LPP1, LPP2, and LPP3, and the character patterns CPA1, CPA2, CPP1, and CPP2 may be located on different layers.

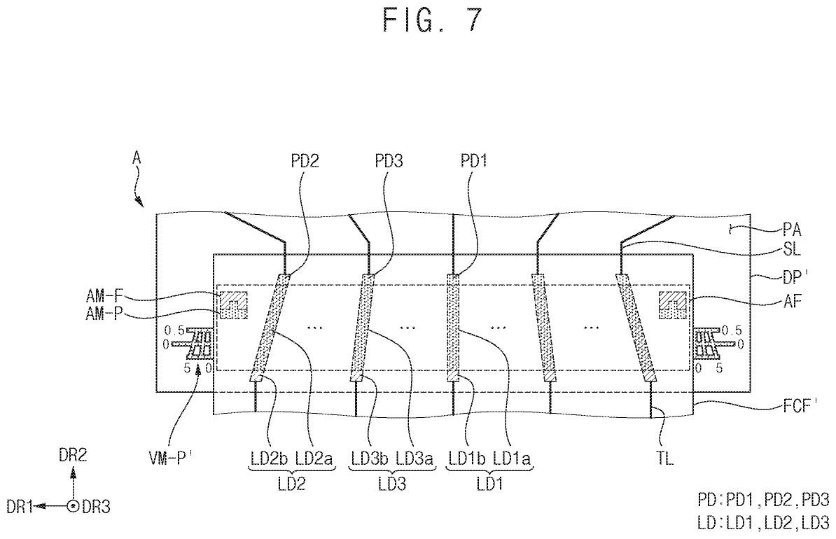

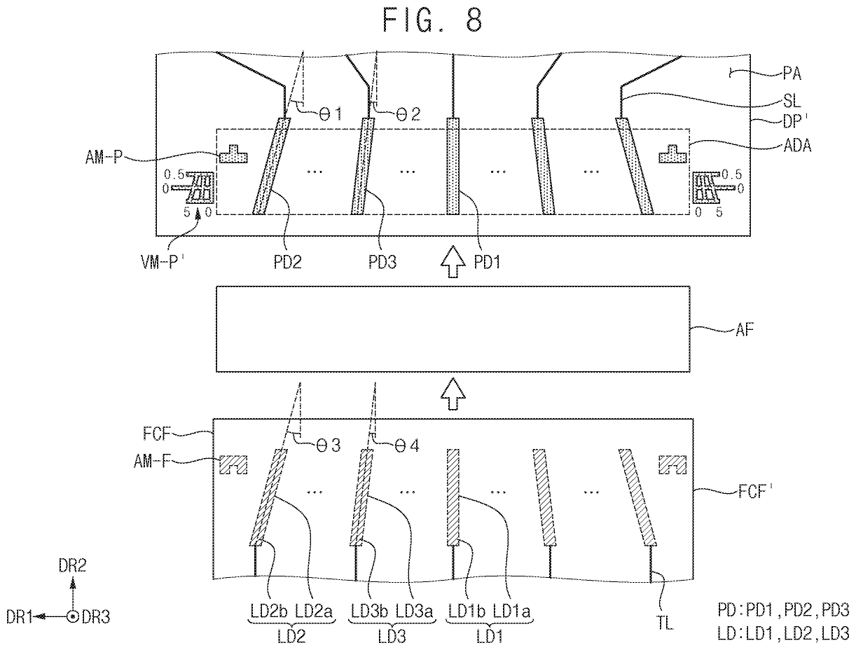

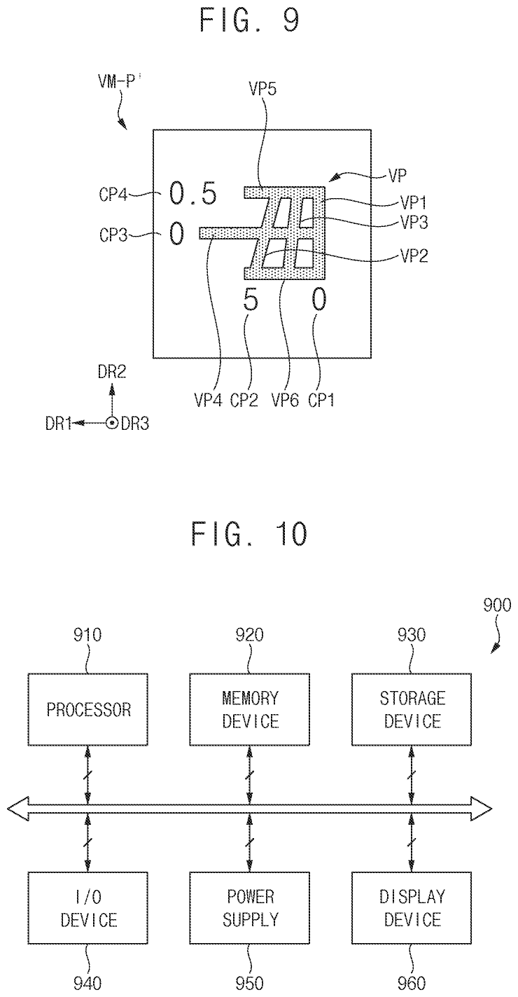

FIG. 7 is an enlarged view illustrating another example of an area A of FIG. 1. FIG. 8 is an exploded plan view of the display device of FIG. 7. FIG. 9 is an enlarged view illustrating a panel vernier mark of FIG. 8.

Referring to FIGS. 7 to 9, according to some embodiments, the first panel vernier mark VMA-P and the second panel vernier mark VMP-P described with reference to FIGS. 4 to 6 may be integrally formed, and the film vernier mark VM-F may be omitted. Hereinafter, some repeated descriptions may be omitted or simplified.

According to some embodiments, the display panel DP′ may include the pads PD, the panel alignment mark AM-P, and the panel vernier mark VM-P′ located in the peripheral area PA. The pads PD, the panel alignment mark AM-P, and the panel vernier mark VM-P′ may be located on the upper surface of the base substrate BS of FIG. 3.

The flexible circuit film FCF′ may include the base film, and the leads LD and the film alignment mark AM-F located on one surface of the base film. According to some embodiments, the film vernier mark VM-F of FIGS. 4 to 6 may be omitted.

The panel vernier mark VM-P′ may be spaced apart from the second pad PD2 in the first direction DR1. According to some embodiments, the panel vernier mark VM-P′ may not overlap the conductive adhesive AF in a plan view. That is, the panel vernier mark VM-P′ may be located outside the conductive adhesive AF in a plan view. According to some embodiments, the panel vernier mark VM-P′ may not overlap the flexible circuit film FCF' in a plan view.

According to some embodiments, as illustrated in FIG. 9, the panel vernier mark VM-P′ may include a vernier pattern VP having a shape where the first to sixth extension patterns LPA1, LPA2, LPA3, LPP1, LPP2, and LPP3 of FIG. 6 are coupled to each other. The vernier pattern VP may be electrically insulated from the pads PD.

The vernier pattern VP may include first to third extension portions VP1, VP2, and VP3 extending to be inclined at different angles with respect to the second direction DR2 and fourth to sixth extension portions VP4, VP5, and VP6 extending in the first direction DR1 and arranged along the second direction DR2. According to some embodiments, the first to sixth extension portions VP1, VP2, VP3, VP4, VP5, and VP6 may be integrally formed.

The first extension portion VP1 may extend in parallel (or substantially in parallel) to the first pad PD1. That is, the first extension portion VP1 may extend in the second direction DR2. An extension direction of the first extension portion VP1 may be parallel (or substantially parallel) to the second direction DR2. An inclination angle of the first extension portion VP1, which is an acute angle between the extension direction of the first extension portion VP1 and the second direction DR2, may be 0 degrees.

The second extension portion VP2 may be located in the first direction DR1 from the first extension portion VP1. The second extension portion VP2 may extend in parallel (or substantially in parallel) to the second pad PD2. That is, the second extension portion VP2 may extend to be inclined at the first angle θ1 with respect to the second direction DR2. An inclination angle of the second extension portion VP2, which is an acute angle between an extension direction of the second extension portion VP2 and the second direction DR2, may be the first angle θ1. The inclination angle of the second extension portion VP2 may be greater than the inclination angle of the first extension portion VP1.

The third extension portion VP3 may be located between the first extension portion VP1 and the second extension portion VP2. That is, the third extension portion VP3 may be located in the first direction DR1 from the first extension portion VP1 and may be located in the direction opposite to the first direction DR1 from the second extension portion VP2. The third extension portion VP3 may extend in parallel (or substantially in parallel) to the third pad PD3. The third extension portion VP3 may extend to be inclined at the second angle θ2 with respect to the second direction DR2. An inclination angle of the third extension portion VP3, which is an acute angle between an extension direction of the third extension portion VP3 and the second direction DR2, may be the second angle θ2. The inclination angle of the third extension portion VP3 may be greater than the inclination angle of the first extension portion VP1, and may be less than the inclination angle of the second extension portion VP2.

The fourth extension portion VP4 may extend in the first direction DR1 and may cross each of the first to third extension portions VP1, VP2, and VP3.

The fifth extension portion VP5 may extend in the first direction DR1 and may be located in the second direction DR2 from the fourth extension portion VP4. The fifth extension portion VP5 may cross each of the first to third extension portions VP1, VP2, and VP3. According to some embodiments, a length of the fifth extension portion VP5 in the first direction DR1 may be less than a length of the fourth extension portion VP4 in the first direction DR1.

The sixth extension portion VP6 may extend in the first direction DR1 and may be located in the direction opposite to the second direction DR2 from the fourth extension portion VP4. The sixth extension portion VP6 may cross each of the first to third extension portions VP1, VP2, and VP3. According to some embodiments, a length of the sixth extension portion VP6 in the first direction DR1 may be less than the length of the fourth extension portion VP4 in the first direction DR1. According to some embodiments, the length of the sixth extension portion VP6 in the first direction DR1 may be the same (or substantially the same) as the length of the fifth extension portion VP5 in the first direction DR1.

According to some embodiments, a distance between the fourth extension portion VP4 and the fifth extension portion VP5 in the second direction DR2 may be the same (or substantially the same) as a distance between the fourth extension portion VP4 and the sixth extension portion VP6 in the second direction DR2.

According to some embodiments, the panel vernier mark VM-P′ may further include first to fourth character patterns CP1, CP2, CP3, and CP4 adjacent to the vernier pattern VP.

The first character pattern CP1 may be adjacent to the first extension portion VP1. The first character pattern CP1 may indicate an angle in which the extension direction of the first extension portion VP1 is inclined with respect to the second direction DR2. That is, the first character pattern CP1 may indicate the inclination angle of the first extension portion VP1.

The second character pattern CP2 may be adjacent to the second extension portion VP2. The second character pattern CP2 may indicate an angle in which the extension direction of the second extension portion VP2 is inclined with respect to the second direction DR2. That is, the second character pattern CP2 may indicate the inclination angle of the second extension portion VP2.

The third character pattern CP3 may be adjacent to the fourth extension portion VP4, and the fourth character pattern CP4 may be adjacent to the fifth extension portion VP5. The fourth character pattern CP4 may indicate the distance between the fourth extension portion VP4 and the fifth extension portion VP5 in the second direction DR2.

According to some embodiments, by measuring an angle between the second extension portion VP2 of the panel vernier pattern VP and the second portion LD2b of the second lead LD2 using a magnifier or the like, a degree of twisting between the display panel DP′ and the flexible circuit film FCF′ may be accurately measured. The second portion LD2b of the second lead LD2 is a portion that does not overlap the conductive adhesive AF, thus, the second portion LD2b may be easily observed below the display panel DP′. In addition, by further measuring an angle between each of the first and third extension portions VP1 and VP3 having different inclination angles and the second portion LD2b of the second lead LD2, the degree of twisting between the display panel DP′ and the flexible circuit film FCF′ may be more accurately measured. Based on this, the flexible circuit film FCF′ may be rotated (or tilted) such that the second extension portion VP2 of the panel vernier pattern VP and the second portion LD2b of the second lead LD2 are parallel to each other, thus, the display panel DP′ and the flexible circuit Film FCF′ may be precisely aligned.

According to some embodiments, by measuring a distance between the fourth extension portion VP4 of the panel vernier pattern VP and a reference point of the flexible circuit film FCF′ in the second direction DR2 using a magnifier or the like, a degree of position error in the second direction DR2 between the display panel DP′ and the flexible circuit film FCF′ may be accurately measured. In addition, by further measuring a distance between each of the fifth and sixth extension portions VP5 and VP6 spaced apart from the fourth extension portion VP4 with an interval (e.g., a set o predetermined interval) and the reference point of the flexible circuit film FCF′ in the second direction DR2, the degree of position error in the second direction DR2 between the display panel DP′ and the flexible circuit film FCF′ may be more accurately measured. Based on this, the flexible circuit film FCF′ may be moved such that the reference point of the flexible circuit film FCF′ is located on the same line as the fourth extension portion VP4 of the panel vernier pattern VP (e.g., such that a distance between the reference point and the fourth extension portion VP4 in the second direction DR2 is zero), thus, the display panel DP′ and the flexible circuit Film FCF′ may be precisely aligned. Accordingly, a reliability of the display device DD' may be relatively improved.

According to some embodiments, the panel vernier mark VM-P′ may be used as a reference for both the twisting alignment and the position alignment of the display panel DP′ and the flexible circuit film FCF′. Thus, a size of an area occupied by a vernier mark for precisely alignment of the display panel DP′ and flexible circuit film FCF′ may be relatively reduced.

FIG. 10 is a block diagram illustrating an electronic device according to some embodiments.

FIG. 10 is a block diagram illustrating an electronic device according to some embodiments.

Referring to FIG. 10, according to some embodiments, an electronic device 900 may include a processor 910, a memory device 920, a storage device 930, an input/output (“I/O”) device 940, a power supply 950, and a display device 960. Here, the display device 960 may correspond to the display device DD of FIG. 1. The electronic device 900 may further include a plurality of ports for communicating with a video card, a sound card, a memory card, a universal serial bus (“USB”) device, or the like. According to some embodiments, the electronic device 900 may be implemented as a television. According to some embodiments, the electronic device 900 may be implemented as a smart phone. However, embodiments are not limited thereto, and according to some embodiments, the electronic device 900 may be implemented as a cellular phone, a video phone, a smart pad, a smart watch, a tablet personal computer (“PC”), a car navigation system, a computer monitor, a laptop, a head (e.g., head mounted) display (“HMD”), or the like.

The processor 910 may perform various computing functions. According to some embodiments, the processor 910 may be a microprocessor, a central processing unit (“CPU”), an application processor (“AP”), or the like. The processor 910 may be coupled to other components via an address bus, a control bus, a data bus, or the like. According to some embodiments, the processor 910 may be coupled to an extended bus such as a peripheral component interconnection (“PCI”) bus.

The memory device 920 may store data for operations of the electronic device 900. According to some embodiments, the memory device 920 may include at least one non-volatile memory device such as an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, or the like, and/or at least one volatile memory device such as a dynamic random access memory (“DRAM”) device, a static random access memory (“SRAM”) device, a mobile DRAM device, or the like.

According to some embodiments, the storage device 930 may include a solid state drive (“SSD”) device, a hard disk drive (“HDD”) device, a CD-ROM device, or the like. According to some embodiments, the I/O device 940 may include an input device such as a keyboard, a keypad, a mouse device, a touchpad, a touch-screen, or the like, and an output device such as a printer, a speaker, or the like.

The power supply 950 may provide power for operations of the electronic device 900. The power supply 950 may provide power to the display device 960. The display device 960 may be coupled to other components via the buses or other communication links. According to some embodiments, the display device 960 may be included in the I/O device 940.

Although aspects of some embodiments and implementations have been described herein, other embodiments and modifications will be apparent from this description. Accordingly, the invention is not limited to such embodiments, but rather to the broader scope of the appended claims and various modifications and equivalent arrangements as would be apparent to a person of ordinary skill in the art.

What is claimed is:

1. A display device comprising:
a display panel including:
a base substrate including a display area and a peripheral area outside the display area,
pixels in the display area,
pads in the peripheral area, the pads being spaced apart from each other in a first direction, and
a panel vernier mark in the peripheral area, the panel vernier mark being spaced apart from the pads in the first direction;
a flexible circuit film attached on the display panel, the flexible circuit film including a base film and leads on the base film, the leads respectively overlapping the pads in a plan view; and
a conductive adhesive between the display panel and the flexible circuit film, the conductive adhesive respectively connecting the pads and the leads,
wherein the pads include a first pad extending in a second direction perpendicular to the first direction and a second pad extending to be inclined at a first angle with respect to the second direction, and
wherein the panel vernier mark includes a first extension pattern extending in parallel to the first pad and a second extension pattern extending in parallel to the second pad.

2. The display device of claim 1, wherein the first extension pattern extends in the second direction, and the second extension pattern extends to be inclined at the first angle with respect to the second direction.

3. The display device of claim 1, wherein the second pad is spaced apart from the first pad in the first direction,
wherein the first extension pattern is spaced apart from the second pad in the first direction, and
wherein the second extension pattern is spaced apart from the first extension pattern in the first direction.

4. The display device of claim 3, wherein the first pad is at a center among the pads, and the second pad is at an outermost location among the pads.

5. The display device of claim 3, wherein the pads further include a third pad between the first pad and the second pad and extending to be inclined at a second angle less than the first angle with respect to the second direction, and
wherein the panel vernier mark further includes a third extension pattern extending in parallel to the third pad.

6. The display device of claim 5, wherein the third extension pattern is between the first extension pattern and the second extension pattern and extends to be inclined at the second angle with respect to the second direction.

7. The display device of claim 1, wherein the panel vernier mark further includes a first character pattern indicating an angle in which an extension direction of the second extension pattern is inclined with respect to the second direction.

8. The display device of claim 7, wherein the first character pattern is adjacent to the second extension pattern.

9. The display device of claim 1, wherein the panel vernier mark further includes:
a fourth extension pattern extending in the first direction, and
a fifth extension pattern extending in the first direction and spaced apart from the fourth extension pattern in the second direction.

10. The display device of claim 9, wherein the panel vernier mark further includes a second character pattern indicating a distance between the fourth extension pattern and the fifth extension pattern in the second direction.

11. The display device of claim 10, wherein the second character pattern is adjacent to the fifth extension pattern.

12. The display device of claim 9, wherein the fourth extension pattern and the fifth extension pattern are spaced apart from the first extension pattern and the second extension pattern in the first direction.

13. The display device of claim 12, wherein in the plan view, the conductive adhesive overlaps the first extension pattern and the second extension pattern and does not overlap the fourth extension pattern and the fifth extension pattern.

14. The display device of claim 12, wherein in the plan view, the flexible circuit film overlaps the first extension pattern and the second extension pattern and does not overlap the fourth extension pattern and the fifth extension pattern.

15. The display device of claim 14, wherein the leads include:
a first lead extending in the second direction and overlapping the first pad in the plan view, and
a second lead extending to be inclined at the first angle with respect to the second direction and overlapping the second pad in the plan view,
wherein the flexible circuit film is spaced apart from the leads in the first direction and further includes a film vernier mark extending in parallel to the second lead.

16. The display device of claim 15, wherein the film vernier mark overlaps the second extension pattern in the plan view.

17. The display device of claim 9, wherein the first extension pattern, the second extension pattern, the fourth extension pattern, and the fifth extension pattern are integrally formed.

18. The display device of claim 17, wherein the conductive adhesive does not overlap the first extension pattern, the second extension pattern, the fourth extension pattern, and the fifth extension pattern in the plan view.

19. The display device of claim 17, wherein the flexible circuit film does not overlap the first extension pattern, the second extension pattern, the fourth extension pattern, and the fifth extension pattern in the plan view.

20. A display device comprising:
a display panel including:
a base substrate including a display area and a peripheral area outside the display area,
pixels in the display area,
pads in the peripheral area, the pads being spaced apart from each other in a first direction, and
a panel vernier mark in the peripheral area, the panel vernier mark being spaced apart from the pads in the first direction;
a flexible circuit film attached on the display panel, the flexible circuit film including a base film and leads on the base film, the leads respectively overlapping the pads in a plan view; and
a conductive adhesive between the display panel and the flexible circuit film, the conductive adhesive respectively connecting the pads and the leads,
wherein the pads include a first pad extending in a second direction perpendicular to the first direction and a second pad extending to be inclined at a first angle with respect to the second direction, and
wherein the panel vernier mark includes:
a first extension portion extending in parallel to the first pad;
a second extension portion extending in parallel to the second pad and arranged in the first direction from the first extension portion;
a third extension portion extending in the first direction and crossing the first extension portion and the second extension portion; and
a fourth extension portion extending in the first direction, arranged in the second direction from the third extension portion, and crossing the first extension portion and the second extension portion.

21. An electronic device comprising:
a display device; and
a power supply configured to provide power to the display device,
wherein the display device comprises:
a display panel including:
a base substrate including a display area and a peripheral area outside the display area,
pixels in the display area,
pads in the peripheral area, the pads being spaced apart from each other in a first direction, and
a panel vernier mark in the peripheral area, the panel vernier mark being spaced apart from the pads in the first direction;
a flexible circuit film attached on the display panel, the flexible circuit film including a base film and leads on the base film, the leads respectively overlapping the pads in a plan view; and
a conductive adhesive between the display panel and the flexible circuit film, the conductive adhesive respectively connecting the pads and the leads,
wherein the pads include a first pad extending in a second direction perpendicular to the first direction and a second pad extending to be inclined at a first angle with respect to the second direction, and
wherein the panel vernier mark includes a first extension pattern extending in parallel to the first pad and a second extension pattern extending in parallel to the second pad.
